(19) United States
(12) Patent Application Publication
(10) Pub. No.: US 2007/0063250 A1
(43) Pub. Date: Mar. 22, 2007

(54) Split gate field effect transistor device with aligned gate electrode sidewalls

(75) Inventors: Haw-Chuan Wu, Kaohsiung City (TW); Wong-Chu Chu, Hsin Chu Hsien (TW); Dah-Chuen Ho, Taichung City (TW); Kuang Yang, Baoshan Township (TW)

Correspondence Address: THOMAS, KAYDEN, HOSTEMEYER & RISLEY LLP, 100 GALLERIA PARKWAY, SUITE 1750, ATLANTA, GA, 30339, US

(73) Assignee: Taiwan Semiconductor Manufacturing Co., Ltd.

(21) Appl. No.: 11/230,348

(22) Filed: Sep. 20, 2005

(51) Int. Cl. H01L 29/788

(52) U.S. Cl. 257/315

(57) ABSTRACT

A split gate field effect transistor is fabricated with a sidewall of a control gate electrode aligned with a sidewall of a floating gate electrode. The aligned sidewalls are on a side of the split gate field effect transistor device opposite the control gate electrode channel of the split gate field effect transistor device. The aligned sidewalls provide for enhanced performance of the split gate field effect transistor device.

### BACKGROUND OF THE INVENTION

1. Field of the Invention

The invention relates generally to split gate field effect transistor devices. More particularly, the invention relates to split gate field effect transistor devices with enhanced performance.

2. Description of the Related Art

Semiconductor products typically include field effect transistor devices that are employed as switching devices within both logic circuits and memory circuits.

A variation of a field effect transistor device that is employed within a memory circuit is a split gate field effect transistor device. Split gate field effect transistor devices function as non-volatile data storage components within integrated circuits. They are structurally related to conventional field effect transistor devices insofar as they both include a channel region that separates source and drain regions within a semiconductor substrate. A conventional field effect transistor device employs a single gate electrode completely covering the channel region. However, a split gate field effect transistor device typically employs: (1) a floating gate electrode covering a floating gate electrode channel portion of the channel region; and (2) a control gate electrode covering a portion of the floating gate electrode as well as a control gate electrode channel portion of the channel region. Particular sets of voltages applied to a semiconductor substrate, source/drain regions and control gate electrode provide for charge injection or rejection with respect to the floating gate electrode, thus providing non-volatile data storage capabilities within the split gate field effect transistor device.

While split gate field effect transistor devices are quite common in the semiconductor fabrication art, they are nonetheless not entirely without problems. In that regard, it is often difficult to fabricate split gate field effect transistor devices with enhanced performance as split gate field effect transistor device dimensions decrease.

The invention is directed towards the foregoing object.

### SUMMARY OF THE INVENTION

A first object of the invention is to provide a split gate field effect transistor device and a method for fabricating the split gate field effect transistor device.

A second object of the invention is to provide a split gate field effect transistor device and method in accord with the first object of the invention, wherein the split gate field effect transistor device is fabricated with enhanced performance.

In accord with the objects of the invention, the invention provides a semiconductor structure including a split gate field effect transistor device. The semiconductor structure includes a semiconductor substrate having a channel region defined laterally interposed between source and drain regions formed within the semiconductor substrate. The semiconductor structure also includes a tunneling dielectric layer formed upon at least a portion of the channel region, as well as a floating gate electrode formed upon the tunneling dielectric layer and covering a floating gate electrode channel portion of the channel region. The semiconductor structure also includes an intergate electrode dielectric layer formed upon the floating gate electrode, as well as a control gate electrode formed upon the intergate electrode dielectric layer and covering a control gate electrode channel portion of the channel region. Within the semiconductor structure, a sidewall of the floating gate electrode and a sidewall of the control gate electrode opposite the control gate electrode channel region are aligned.

The invention provides a split gate field effect transistor device with enhanced performance and a method for fabricating the split gate field effect transistor device.

The invention realizes the foregoing object by fabricating a split gate field effect transistor device with a sidewall of a floating gate electrode and a sidewall of a control gate electrode being aligned. The aligned sidewalls are opposite a control gate electrode channel region not covered by the floating gate electrode. With such a configuration, a control gate electrode is assured of providing optimal control over a floating gate electrode even when both are formed misaligned. Thus, a split gate field effect transistor device is formed with enhanced performance.

### BRIEF DESCRIPTION OF THE DRAWINGS

The objects, features and advantages of the invention are understood within the context of the Description of the Preferred Embodiment, as set forth below. The Description of the Preferred Embodiment is understood within the context of the accompanying drawings, which form a material part of this disclosure, wherein:

FIG. 1, FIG. 2, FIG. 3, FIG. 4 and FIG. 5 show a series of schematic cross-sectional diagrams illustrating the results of progressive stages in fabricating a semiconductor product including a pair of split gate field effect transistor devices in accord with a preferred embodiment of the invention.

### DESCRIPTION OF THE PREFERRED EMBODIMENT

The invention provides a split gate field effect transistor device with enhanced performance and a method for fabricating the split gate field effect transistor device.

The invention realizes the foregoing object by fabricating a split gate field effect transistor device with a sidewall of a floating gate electrode and a sidewall of a control gate electrode being aligned. The aligned sidewalls are opposite a control gate electrode channel region not covered by the floating gate electrode. With such a configuration, a control gate electrode is assured of providing optimal control over a floating gate electrode even when both are formed misaligned. Thus, a split gate field effect transistor device is formed with enhanced performance.

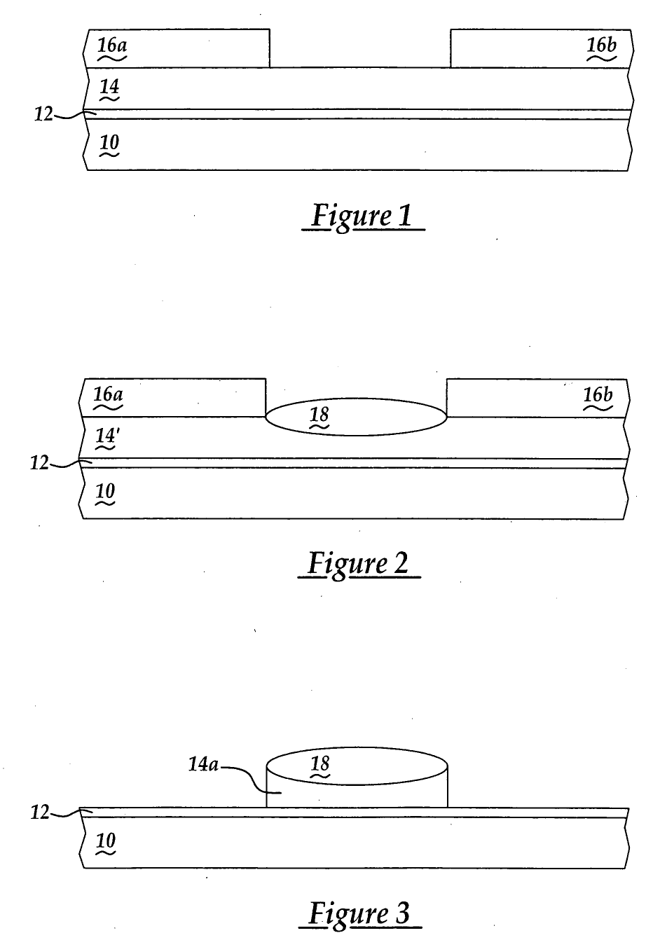

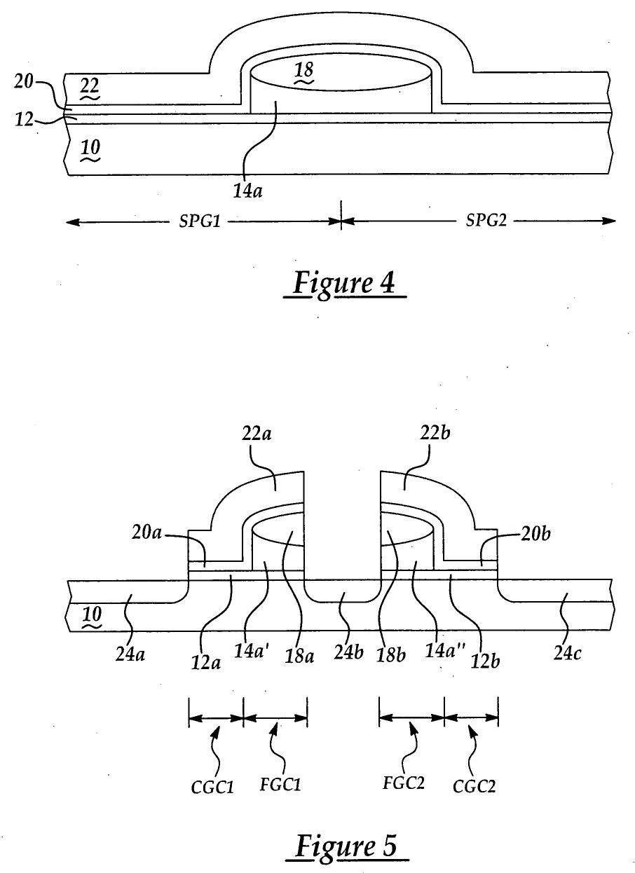

FIG. 1 to FIG. 5 show a series of schematic cross-sectional diagrams illustrating the results of progressive stages in fabricating a semiconductor product including a pair of split gate field effect transistor devices in accord with a preferred embodiment of the invention. FIG. 1 shows a schematic cross-sectional diagram of the semiconductor product at an early stage in its fabrication.

FIG. 1 shows a semiconductor substrate 10. A blanket tunneling dielectric layer 12 is formed upon the semiconductor substrate 10. A blanket floating gate electrode layer 14 is formed upon the blanket tunneling dielectric layer. 12. A pair of patterned oxidation mask layers 16a and 16b is formed upon the blanket floating gate electrode layer 14.

The semiconductor substrate 10 may be formed of a semiconductor material as is otherwise conventional in the semiconductor product fabrication art. Such semiconductor materials may include, but are not limited to, silicon semiconductor materials, germanium semiconductor materials, silicon-germanium alloy semiconductor materials and semiconductor-on-insulator semiconductor materials. Typically the semiconductor substrate 10 is a silicon semiconductor substrate of an appropriate dopant polarity, dopant concentration and crystallographic orientation.

The blanket tunneling dielectric layer 12 may be formed of tunneling dielectric materials as are otherwise conventional in the semiconductor product fabrication art. Typically the blanket tunneling dielectric layer 12 is formed of a thermal silicon oxide dielectric material, formed to a thickness of from about 50 to about 150 angstroms. Alternative dielectric materials with appropriate etch stop properties may be desirable in the invention.

The blanket floating gate electrode layer 14 is typically formed of a doped polysilicon material having a dopant concentration of from about 1E18 to about 1E22 dopant atoms per cubic centimeter. Typically, the blanket floating gate electrode layer 14 is formed to a thickness of from about 1500 to about 3000 angstroms.

Finally, the pair of patterned oxidation mask layers 16a and 16b is formed of an oxidation resistant material such as a silicon nitride material or a silicon oxynitride material. Typically, the pair of patterned oxidation mask layers 16a and 16b is formed to a thickness of from about 1500 to about 3000 angstroms.

FIG. 2 shows the results of thermally oxidizing the semiconductor product of FIG. 1 to form a thermal oxide layer 18 upon a partially oxidized blanket floating gate electrode layer 14′, while employing the pair of patterned oxidation mask layers 16a and 16b as oxidation mask layers. The thermal oxidation may be undertaken at a temperature of from about 800 to about 1200 degrees centigrade for a time period of from about 0.5 to about 2.0 hours, to provide the thermal oxide layer 18 of thickness from about 500 to about 1500 angstroms.

FIG. 3 first shows the results of stripping the pair of patterned oxidation mask layers 16a and 16b from the semiconductor product of FIG. 2. FIG. 3 also shows the results of etching the partially oxidized blanket floating gate electrode layer 14′ to form a patterned floating gate electrode layer 14a. The etching is undertaken while employing the thermal oxide layer 18 as an etch mask layer.

The pair of patterned oxidation mask layers 16a and 16b may be stripped employing stripping methods and materials as are conventional in the semiconductor product fabrication art. When formed of a silicon nitride or a silicon nitride containing material, they may be stripped employing aqueous phosphoric acid containing materials at elevated temperatures.

The partially oxidized blanket gate electrode layer 14′ may be etched to form the patterned floating gate electrode layer 14a while employing etchants as are otherwise also conventional in the semiconductor product fabrication art. Such etchants will typically be anisotropic plasma etchants.

FIG. 4 first shows the results of forming a blanket intergate electrode dielectric layer 20 upon the semiconductor product of FIG. 3. In addition, FIG. 4 also shows a blanket control gate electrode layer 22 formed upon the blanket intergate electrode dielectric layer 20.

The blanket intergate electrode dielectric layer 20 may be formed of dielectric materials as are otherwise conventional in the semiconductor product fabrication art. Such dielectric materials may include, but are not limited to silicon oxide dielectric materials and silicon nitride dielectric materials. Typically, the blanket intergate electrode dielectric layer 20 is formed to a thickness of from about 10 to about 50 angstroms. Typically, the blanket intergate electrode dielectric layer 20 is formed of a different dielectric material than the blanket tunneling dielectric layer 12 such as to provide for appropriate etch stop properties which are also desired for the blanket tunneling dielectric layer 12 with respect to the thermal oxide layer 18. Thus, the latter two dielectric layers are preferably also formed of different dielectric materials.

The blanket control gate electrode layer 22 may be, and typically is, formed of a conductor material analogous, equivalent or identical to the conductor material from which is formed the blanket floating gate electrode layer 14. Typically, the blanket control gate electrode layer 22 is formed to a thickness of from about 1500 to about 3000 angstroms.

FIG. 5 shows the results of a masked anisotropic etching of the semiconductor product of FIG. 4 to form a mirrored pair of split gate field effect transistor device structures SPG1 and SPG2. Patterned mask layers as employed within the masked anisotropic etching are omitted. The mirrored pair of split gate field effect transistor device structures SPG1 and SPG2 includes a pair of patterned tunneling dielectric layers 12a and 12b. A pair of floating gate electrodes 14a′ and 14a″ is formed upon the pair of patterned tunneling dielectric layers 12a and 12b and covering a pair of floating gate electrode channel regions FGC1 and FGC2 within the semiconductor substrate 10. A pair of patterned thermal oxide layers 18a and 18b is aligned upon the pair of floating gate electrodes 14a′ and 14a″. A pair of patterned intergate electrode dielectric layers 20a and 20b is formed upon exposed portions of the patterned thermal oxide layers 18a and 18b, the floating gate electrodes 14a′ and 14a″ and the patterned tunneling dielectric layers 12a and 12b over a pair of control gate electrode channel regions CGC1 and CGC2 of the semiconductor substrate 10. A pair of control gate electrodes 22a and 22b is formed upon the pair of patterned intergate electrode dielectric layers 20a and 20b and completely covering the channel regions. The foregoing sequential patterning may be undertaken employing methods as are conventional in the semiconductor product fabrication art.

FIG. 5 also shows a series of source/drain regions 24a, 24b and 24c formed into the semiconductor substrate 10 while employing remaining split gate field effect transistor device structures as a mask. The mirrored pair of split gate field effect transistor device structures SPG1 and SPG2 shares the source/drain region 24b, which typically functions as a source region.

Within the invention, each of the pair of split gate field effect transistor device structures SPG1 and SPG2 as illustrated in FIG. 5 has a sidewall of a control gate electrode 22a or 22b aligned with a sidewall of a floating gate electrode 14a′ or 14a″. The aligned sidewalls are opposite the control gate electrode channels CGC1 and CGC2 of the pair of split gate field effect transistor devices. Such alignment provides enhanced performance of the pair of split gate field effect transistor devices since overlap of a control gate with a floating gate is predictable. In addition, under circumstances of misalignment of a mask when forming the semiconductor product of FIG. 5 from the semiconductor product of FIG. 4, a comparatively longer floating gate electrode will be paired with a comparatively shorter control gate electrode and a comparatively shorter floating gate electrode will be paired with a comparatively longer control gate electrode. This resulting pairing in misalignment also provides enhanced performance within a split gate field effect transistor device fabricated in accord with the invention. The former pairing provides improves source-to-drain punchthrough properties. The latter pairing provides improved programming efficiency.

The preferred embodiment of the invention is illustrative of the invention rather than limiting of the invention. Revisions and modifications may be made to methods, materials, structures and dimensions of a split gate field effect transistor device in accord with the preferred embodiment of the invention while still providing a split gate field effect transistor device in accord with the invention, further in accord with the accompanying claims.

1. A semiconductor structure including a split gate field effect transistor device comprising:
a semiconductor substrate having a channel region defined laterally interposed between source and drain regions formed within the semiconductor substrate;
a tunneling dielectric layer formed upon at least a portion of the channel region;
a first gate electrode formed upon the tunneling dielectric layer and covering a first gate electrode channel portion of the channel region;
an intergate electrode dielectric layer formed upon the first gate electrode and partially contacted with the tunneling dielectric layer; and
a second gate electrode formed upon the intergate electrode dielectric layer covering a second gate electrode channel portion of the channel region, wherein the first gate electrode has a first sidewall and the second gate electrode has a second sidewall aligned with the first sidewall.

2. The semiconductor structure of claim 1 wherein the tunneling dielectric layer is formed to a thickness of from about 50 to about 150 angstroms.

3. The semiconductor structure of claim 1 wherein the first gate electrode is floating gate electrode and the second gate electrode is control gate electrode.

4. The semiconductor structure of claim 1 wherein the intergate electrode dielectric layer is formed to a thickness of from about 10 to about 50 angstroms.

5. The semiconductor structure of claim 1 wherein the second gate electrode is formed to a thickness of from about 1500 to about 3000 angstroms.

6. The semiconductor structure of claim 1 further comprising a second split gate field effect transistor device mirroring the split gate field effect transistor device.

7. The semiconductor structure of claim 6 wherein the split gate field effect transistor device and the second split gate field effect transistor device share a source/drain region.

8-20. (canceled)

21. A semiconductor structure including a split gate field effect transistor device, comprising:
a semiconductor substrate having a floating gate channel and a control gate channel;
a tunneling dielectric layer formed on semiconductor substrate;
a floating gate electrode formed on the tunneling dielectric layer and the floating gate channel;
an integrate electrode dielectric layer formed upon the floating gate electrode and partially contacted with the tunneling dielectric layer to form a stacked dielectric layer; and
a control gate electrode formed upon the intergate electrode dielectric layer, wherein the stacked dielectric layer is interposed between the control gate channel and the control gate electrode.

22. The semiconductor structure of claim 21, wherein the floating gate electrode is vertically aligned with the control gate electrode.

23. The semiconductor structure of claim 22, further comprising a thermal oxide between the floating gate electrode and the intergate electrode dielectric layer, wherein the thermal oxide is vertically aligned with the floating gate electrode and the control gate electrode.
